(19) United States
(12) Patent Application Publication
(10) Pub. No.: US 2022/0406693 A1
(43) Pub. Date: Dec. 22, 2022

(54) INTELLIGENT POWER MODULE

(71) Applicant: Richtek Technology Corporation, Zhubei City (TW)

(72) Inventors: Lung-Sheng Lin, Taichung (TW); Chih-Feng Huang, Hsinchu (TW)

(21) Appl. No.: 17/736,445

(22) Filed: May 4, 2022

(30) Foreign Application Priority Data
Jun. 21, 2021 (TW) 110122621

(51) Int. Cl. H01L 23/495; H01L 23/00; H01L 25/065; H01L 21/48; H01L 21/56; H01L 23/31

(52) U.S. Cl. CPC H01L 23/49568; H01L 24/73; H01L 24/32; H01L 24/48; H01L 25/0655; H01L 23/49555; H01L 23/49575; H01L 21/4821; H01L 21/4882; H01L 21/56; H01L 23/3107; H01L 2224/73265; H01L 2224/48137; H01L 2224/48245; H01L 2924/37001; H01L 2924/182; H01L 2924/3511

(57) ABSTRACT

An intelligent power module includes: an encapsulating material structure; a lead frame which is at least partially encapsulated inside the encapsulating material structure, wherein all portions of the lead frame encapsulated inside the encapsulating material structure are at a same planar level; and a heat dissipation structure, which is connected to the lead frame.

### CROSS REFERENCE

The present invention claims priority to TW 110122621 filed on Jun. 21, 2021.

### BACKGROUND OF THE INVENTION

### Field of Invention

The present invention relates to an intelligent power module, in particular to an intelligent power module including a lead frame maintained at the same planar level after packaging.

### Description of Related Art

Please refer to FIGS. 1A and 1B, which show a prior art intelligent power module 10. FIG. 1B shows a cross section according to a cross-section line AA in FIG. 1A. In FIG. 1B, a lead frame 110 includes a bending part to form a downset for disposing the chips CH1 and CH2, wherein a heat dissipation structure 120 is placed on the opposite side of the downset. The downward configuration of the downset pushes the heat dissipation structure 120 more outwardly to be exposed on an outer surface of the intelligent power module 10, so that the heat dissipation structure 120 can perform direct heat transfer to a heat sink on the surface of the intelligent power module 10. However, the process to form the bending often causes many issues, such as: the instability of plastic deformation in the lead frame 110, spring back of the bent structure, uneven thermal expansion between the inner and outer corners of the bent structure caused during temperature changes, and surface damage on the lead frame 110 caused by a long-term used bending tool. These negative factors can result in insufficient surface flatness on the downset, which may cause poor thermal contact between the heat dissipation structure and the lead frame, and residual stress at the connecting portion between the chip and the lead frame, affecting the stability of the chip attachment and the heat dissipation performance.

FIG. 2A shows a heat dissipation structure (white rectangular portion on the package surface) exposed on an outer surface of the prior art intelligent power module. FIG. 2B shows the location relationships among the chips CH3, CH4, CH5, CH6 and the lead frame 110 in the intelligent power module of the prior art. The downset of the lead frame 110 accommodates the chips CH5 and CH6, and the opposite side of the downset is provided with the heat dissipation structure 120. The downset formed in the lead frame 110 is encapsulated inside the packaging material. The lead frame 110 with the downset has the problem of insufficient surface flatness as mentioned above.

When the thermal contact between the heat dissipation structure 120 and the lead frame 110 is not good, heat dissipation performances of the chips CH5 and CH6 become poor to negatively affect the chip operation performances. That is, the heat dissipation performances of the chips are affected by the surface flatness of the lead frame 110. Therefore, it is important to maintain the surface flatness of the lead frame 110 for good heat dissipation performances.

Please refer to FIG. 2B, some of the chips (for example, CH5 and CH6) are disposed on the downset of the lead frame 110, and the other chips (for example, CH3 and CH4) are disposed at another height level on the lead frame 110. This design introduces different top surface heights of the chips CH3, CH4, CH5 and CH6. The difference between such top surface height of the chips CH3, CH4, CH5, and CH6 may affect the positioning accuracy of the bonding wires on the chips CH3, CH4, CH5, and CH6 if the difference is large. When the lead frame 110 has multiple heights, the manufacturing process becomes complicated and often requires adjustments on the tools. Therefore, the poor surface flatness in the prior intelligent power module results in a lower yield.

In view of the drawbacks in the prior art, the present invention provides an intelligent power module which includes a lead frame with an advantage of good surface flatness.

### SUMMARY OF THE INVENTION

In one perspective, the present invention provides an intelligent power module to address the aforementioned problems. The intelligent power module includes: an encapsulating material structure; a lead frame at least partially encapsulated inside the encapsulating material structure, wherein all portions of the lead frame encapsulated inside the encapsulating material structure are at a same planar level; and a heat dissipation structure, connected to the lead frame.

In some embodiments, the lead frame includes a plurality of solder joints encapsulated inside the encapsulating material structure, and a plurality of connection pads outside the encapsulating material structure, wherein the solder joints are at the same planar level.

In one embodiment, signal connections by at least one bonding wire are formed between the lead frame and at least one chip encapsulated inside the encapsulating material structure, or between a plurality of chips encapsulated inside the encapsulating material structure. The lead frame transmits signal to and from the outside of the intelligent power module.

In one embodiment, one side of the heat dissipation structure is exposed to an outside of the encapsulating material structure.

In one embodiment, in a manufacturing process of the intelligent power module, the heat dissipation structure and the chip are disposed on the lead frame by a same fixture, and the manufacturing process for example includes forming bonding pads, reflow, applying a die attach adhesive, etc. In one embodiment, this fixture is reusable. By reusing the fixture, as compared to needing to replace the fixture, the manufacturing time, labor and cost are greatly reduced, and the surface flatness can be better controlled by using the same fixture, whereby the bonding wires W can be bonded substantially at the same height.

In one embodiment, the chips include a micro-controller unit (MCU), a driver chip, a power chip, or other types of chips, or any combination thereof.

Importantly, in the present invention, the portions of the lead frame inside the encapsulating material structure do not include a downset, or any deformation resulting from bending, punching or any other deformation process step.

In one embodiment, a portion of the lead frame outside the encapsulating material structure can be bent when needed. After the encapsulating material structure is formed, the portions of the lead frame inside the encapsulating material structure are fixed by the encapsulating material structure, so that bending the portion of the lead frame outside the encapsulating material structure will not affect the surface flatness of the portions of the lead frame inside the encapsulating material structure.

In one perspective, the present invention provides an intelligent power module manufacturing method, which includes: providing a fixture; disposing a heat dissipation structure on the fixture; placing a lead frame on the fixture, and fastening the lead frame on the heat dissipation structure, wherein all portions of the lead frame are at a same planar level; placing at least one chip on the lead frame, and fastening the chip on the lead frame; taking out the lead frame with the fastened heat dissipation structure and the fastened chip from the fixture; and providing a packaging material, to form an encapsulating material structure encapsulating the lead frame fastened with the heat dissipation structure and the chip. The encapsulating material structure for example can be formed by transfer molding.

In one embodiment, the intelligent power module manufacturing method further includes: after forming the encapsulating material structure, a bent structure of a portion of the lead frame outside the encapsulating material structure is formed.

In one embodiment, the intelligent power module manufacturing method further includes: placing at least another chip on the heat dissipation structure, and fastening this chip on the heat dissipation structure.

The objectives, technical details, features, and effects of the present invention will be better understood with regard to the detailed description of the embodiments below, with reference to the attached drawings.

### BRIEF DESCRIPTION OF THE DRAWINGS

FIGS. 1A, 1B, 2A, and 2B show schematic diagrams of prior art intelligent power modules.

FIGS. 3A, 3B, and 4 show schematic diagrams of intelligent power modules according to two embodiments of the present invention.

FIGS. 5A to 5I are schematic diagrams showing steps of an intelligent power module manufacturing method according to one embodiment of the present invention.

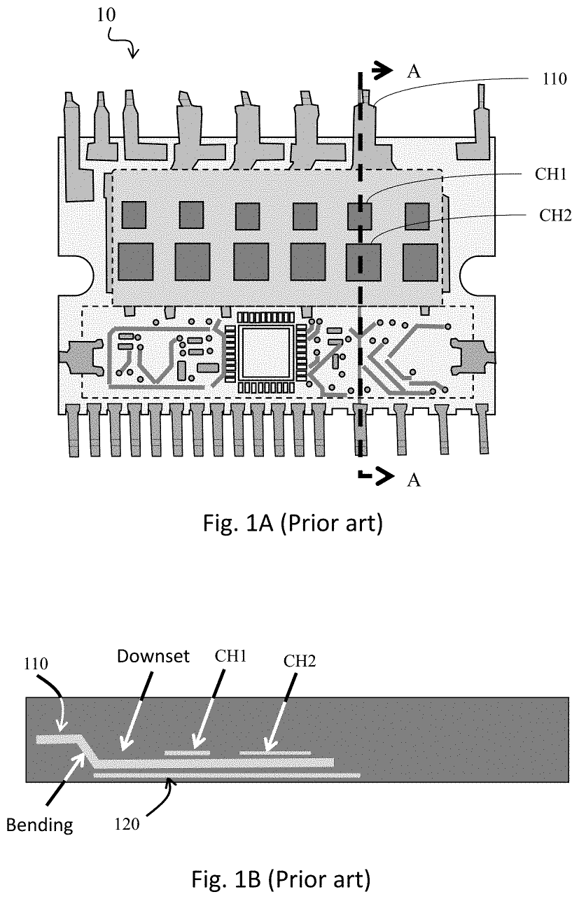

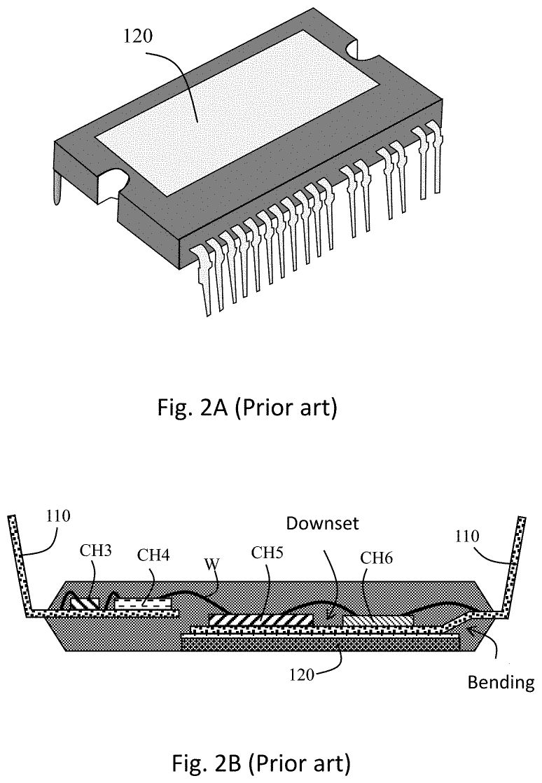

### DESCRIPTION OF THE PREFERRED EMBODIMENTS

The drawings as referred to throughout the description of the present invention are for illustration only, to show the interrelations between the components or units, but not drawn according to actual scale of sizes.

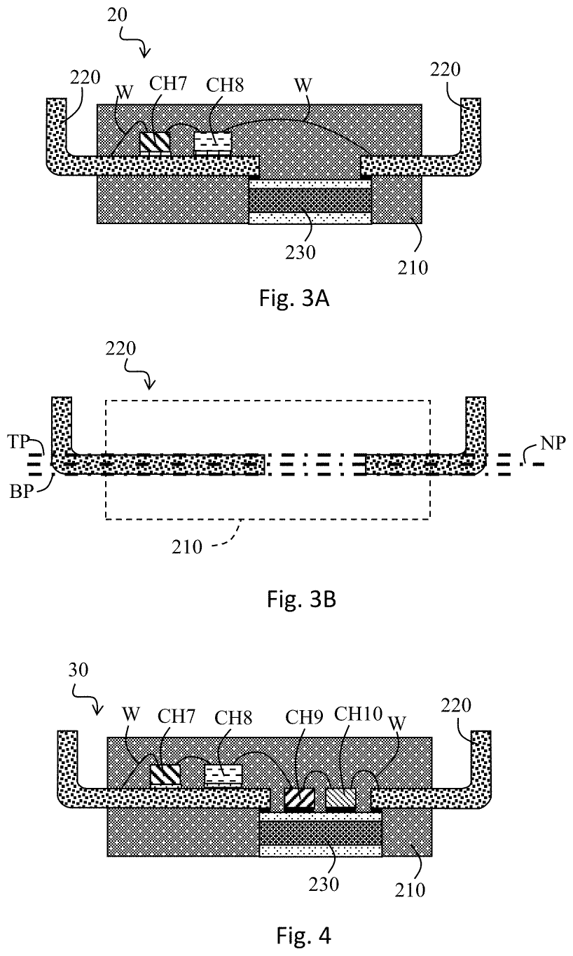

In one perspective, as shown in FIG. 3A or 4, the present invention provides an intelligent power module 20 (or 30) to address the aforementioned surface flatness problem. This intelligent power module 20 (or 30) includes: an encapsulating material structure 210; a lead frame 220, wherein all portions of the lead frame 220 encapsulated inside the encapsulating material structure 210 are at the same planar level (FIG. 3B); and a heat dissipation structure 230, disposed on the lead frame 220.

Please refer to FIG. 3B, the “same planar level” where all the portions of the lead frame 220 encapsulated inside the encapsulating material structure 210 are at, can be defined by either one of the following definitions:

1. The planar level can refer to a neutral plane NP in sheet metal processing. The neutral plane is substantially at the middle position in a cross section of the lead frame 220 encapsulated inside the encapsulating material structure 210. The neutral plane NP is not subject to any processing step that may causes deformation, such as bending or punching; therefore, the lead frame 220 has no residual compressive stress nor residual tensile stress caused by such deformation processing step, and the neutral plane NP does not shift from its original position and remains on the same planar level.
2. The planar level can refer to the top surface TP or the bottom surface BP of the lead frame 220 encapsulated inside the encapsulating material structure 210. The top surface TP or bottom surface BP may be a reference surface for processing, for tool alignment, for use as a contact surface for a tool, or for use as a free surface. The surface flatness of such reference surface is maintained through the whole manufacturing process.

In some embodiments, the lead frame 220 includes plural solder joints encapsulated inside the encapsulating material structure 210 (for example, for transmitting signal to the chips), and plural connection pads outside the encapsulating material structure 210, wherein the solder joints are at the same planar level. That is, the solder joints inside the encapsulating material structure 210 are at the same planar level before encapsulation by the encapsulating material structure 210, and after the encapsulation, the portions of the lead frame 220 including the solder joints encapsulated inside the encapsulating material structure 210 remain at the same planar level.

Since the portions of the lead frame 220 inside the encapsulating material structure 210 are at the same planar level, the chips CH7 and CH8 in FIG. 3A or CH7, CH8, CH9, and CH10 in FIG. 4 on the lead frame 220 are substantially at the same planar level. The heat dissipation structure 230 is disposed on the other side of the lead frame 220 with reference to the chips CH7 and CH8. In short, in FIG. 3A, the chips CH7 and CH8 are disposed on the top surface TP, and the heat dissipation structure 230 is disposed on the bottom surface BP.

As shown in FIG. 4, in another embodiment, the chips CH9 and CH10 are disposed on the heat dissipation structure 230, wherein the chips CH9 and CH10 are inside a slot of the lead frame 110. This arrangement reduces the module size, and increases the heat dissipation performance from the chips CH9 and CH10. The main heat dissipation paths from the chips CH9 and CH10 does not need to pass through the encapsulating material structure 210, but instead, directly passes through the heat dissipation structure 230 to the outside of the intelligent power module 30.

As shown in FIG. 3A or 4, in one embodiment, signal connections are formed between the chips CH7 and CH8 (or among the chips CH7, CH8, CH9 and CH10), or between at least one of the chips and the lead frame 220, via bonding wires W. As such, signals can be transmitted between the chip CH7 and CH8 (or among the chips CH7, CH8, CH9, and CH10) through the among the chips, and signals can be transmitted to and from the outside of the intelligent power module 20 (or 30) through the lead frame 220.

In the embodiment of FIG. 3A or 4, one side of the heat dissipation structure 230 is exposed on an outer surface of the encapsulating material structure 210. In the present invention, the design of the heat dissipation structure 230 can be determined according to practical need, such as a single-layer or multi-layer heat dissipation structure. The total thickness of the heat dissipation structure 230 is substantially equal to a distance between a bottom surface of the lead frame 220 to the outer surface of the encapsulating material structure 210, such that one side of the heat dissipation structure 230 can be exposed on the outer surface of the encapsulating material structure 210. When the heat dissipation structure 230 is a multi-layer structure, the multi-layer structure may be, for example, a multi-layer structure including multiple thermally conductive materials, such as aluminum, copper, ceramics, or a compound or a mixture thereof.

Advantages of the present invention include: surface flatness of the lead frame 220; higher thermal conductivity among the heat dissipation structure 230, the chips, and the lead frame 220; lower residual stress; simpler manufacturing process. In one embodiment, in the manufacturing process of the intelligent power module 20 (or 30), the heat dissipation structure 230, the chips CH7 and CH8 (or CH7, CH8, CH9, and CH10) are disposed on the lead frame 220 by the same tool (such as the same fixture), and the bonding pads forming process step (such as applying solder paste, etc.), reflow process step, and die adhesive applying process, etc., are executed. The related process steps are much simpler, and the tool such as a fixture is reusable. By reusing the fixture, as compared to needing to replace the fixture, the manufacturing time, labor and cost are greatly reduced, and the surface flatness can be better controlled by using the same fixture, whereby the bonding wires W can be bonded substantially at the same height. Furthermore, because of the good the surface flatness, other components also can be arranged on the non-exposed side of the heat dissipation structure 230, to reduce the overall size while keeping good heat dissipation performance.

In one embodiment, the chips may include a micro-controller unit (MCU), a driver chip, a power chip, or other types of chips, or any combination thereof. The chips can be any type of semiconductor chips, such as: analog or digital chips of metal-oxide-semiconductor field effect transistors (MOSFETs), insulated gate bipolar transistor (IGBT) chip, fast recovery diode (FRD) chip, etc.

Importantly, in the present invention, the portions of the lead frame 220 inside the encapsulating material structure 210 do not include a downset, or any deformation resulting from bending, punching or any other deformation process step. Therefore, the portions of the lead frame 220 inside the encapsulating material structure 210 do not have the problems such as unstable plastic deformation, material spring back, uneven thermal expansion between the inner and outer corners in the bent structure due to temperature changes, and surface damage by the bending tool as in the prior art. The present invention has a better surface flatness of the lead frame 220 than the prior art, and less issues.

In one embodiment, a portion of the lead frame 220 which is outside the encapsulating material structure 210 can be bent when needed. After the encapsulating material structure 210 is formed, the portions of the lead frame 220 inside the encapsulating material structure 210 are fixed by the encapsulating material structure 210, so that bending the portion of the lead frame 220 outside the encapsulating material structure 210 will not affect the surface flatness of the portions of the lead frame 220 inside the encapsulating material structure 210. That is, the portion of the lead frame 220 outside the encapsulating material structure 210 can be subject to a deformation process step which is independent from and not limited by the surface flatness requirement of the lead frame 220 inside the encapsulating material structure 210.

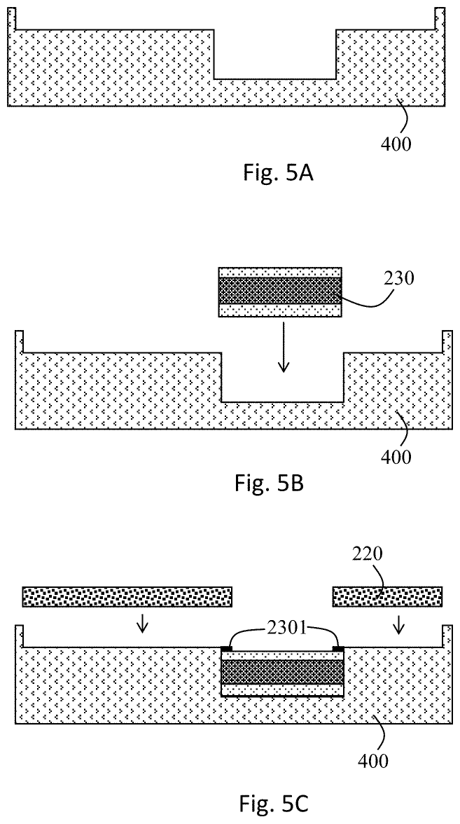

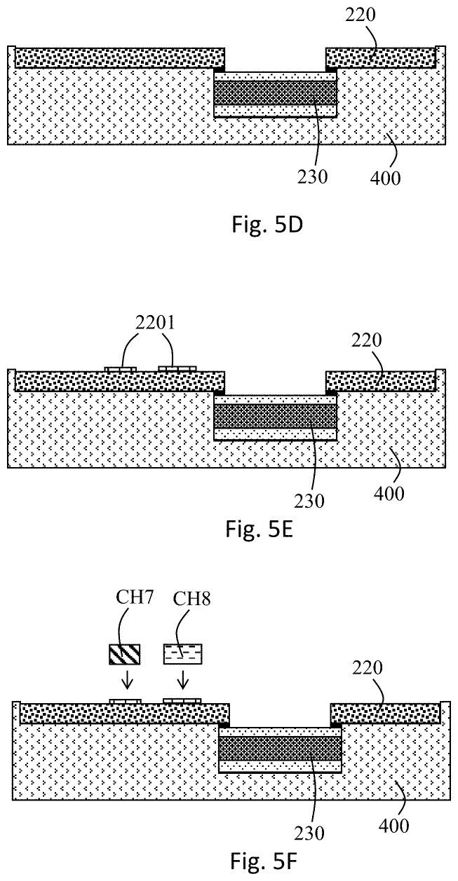

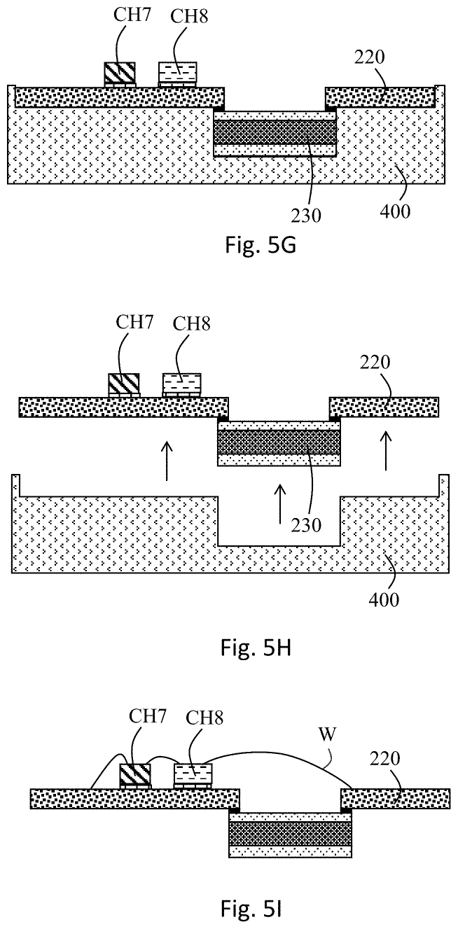

Please refer to FIGS. 5A to 5I. In one perspective, the present invention provides an intelligent power module manufacturing method, including: providing a fixture 400 (FIG. 5A); placing a heat dissipation structure 230 on the fixture 400 (FIG. 5B); forming plural bonding pads 2301 (for example, by applying a solder paste, etc.) on the heat dissipation structure 230, and placing a lead frame 220 on the fixture 400 and the bonding pads 2301 (FIG. 5C); fastening the lead frame 220 on the heat dissipation structure 230 (FIG. 5D), wherein all portions of the lead frame 220 are at the same planar level; applying a die attach adhesive 2201 (for example, a silver glue, etc., FIG. 5E) on the lead frame 220, and placing one or more chips CH7 and CH8 (the number of the chips can be singular or plural) on the die attach adhesive 2201 (FIG. 5F); fastening the chip CH7 and CH8 on the lead frame 220 (FIG. 5G); taking out the heat dissipation structure 230, the lead frame 220, the chips CH7 and CH8 (FIG. 5H) that are fastened to each other, from the fixture 400; forming bonding wires connected between the chips CH7, CH8 and the lead frame 230 (FIG. 5I) by a wire bonding process; and providing a packaging material to encapsulate the heat dissipation structure 230, the lead frame 220, and the chips to form an encapsulating material structure 210 (FIG. 3A or 4), to form the intelligent power module 20 (or 30). In one embodiment, the aforementioned step of forming the encapsulating material structure 210 can be achieved by transfer molding.

In one embodiment, the intelligent power module manufacturing method further includes: after forming the encapsulating material structure 210, bending a portion of the lead frame 220 outside the encapsulating material structure 210 (for example, as shown in FIGS. 3A and 4, the left and right sides of the lead frame 220 are bent upwards).

In one embodiment, the aforementioned step of fastening the lead frame 220 on the heat dissipation structure 230 includes: performing reflow to fasten the heat dissipation structure 230 on the lead frame 220.

In one embodiment, the aforementioned step of fastening the chips CH7 and CH8 on the lead frame 220 includes: baking the die attach adhesive, to fasten the chips CH7 and CH8 on the lead frame 220.

In one embodiment, the intelligent power module manufacturing method further includes: forming bonding wires W connected between the lead frame 220 and the chips CH7, CH8 (or CH7, CH8, CH9, CH10); or forming bonding wires W (FIG. 5I) connected between the chips CH7 and CH8 (or CH7, CH8, CH9, and CH10). The bonding wires W can be made by a wire bonding process.

In one embodiment, the intelligent power module manufacturing method further includes: placing the chips CH9 and CH10 on the heat dissipation structure 230, and fastening the chips CH9 and CH10 on the heat dissipation structure 230, wherein the type and number of chips can be determined according to requirements. For example, the number of chip or chips placed on the heat dissipation structure 230 can be singular or plural.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, two or more of the embodiments can be used together, or, a part of one embodiment can be used to replace a corresponding part of another embodiment. For example, the intelligent power module may have a different number of chips from the drawings, or the components are placed on the fixture in another sequential priority, or the shape of the fixture is different from the drawings. In view of the foregoing, the spirit of the present invention should cover all such and other modifications and variations, which should be interpreted to fall within the scope of the following claims and their equivalents.

What is claimed is:

1. An intelligent power module, including:
an encapsulating material structure;
a lead frame at least partially encapsulated inside the encapsulating material structure, wherein all portions of the lead frame encapsulated inside the encapsulating material structure are at a same planar level; and
a heat dissipation structure, connected to the lead frame.

2. The intelligent power module according to claim 1, wherein the planar level is on a neutral plane, a top surface, or a bottom surface of the portions of the lead frame encapsulated inside the encapsulating material structure.

3. The intelligent power module according to claim 1, wherein the lead frame includes a plurality of solder joints encapsulated inside the encapsulating material structure, and a plurality of connection pads outside the encapsulating material structure, wherein the solder joints are at the same planar level.

4. The intelligent power module according to claim 1, wherein signal connections by at least one bonding wire are formed between the lead frame and at least one chip encapsulated inside the encapsulating material structure, or between a plurality of chips encapsulated inside the encapsulating material structure.

5. The intelligent power module according to claim 1, wherein one side of the heat dissipation structure is exposed to an outside of the encapsulating material structure.

6. The intelligent power module according to claim 1, wherein in a manufacturing process of the intelligent power module, the heat dissipation structure and at least one chip are fastened on the lead frame by a reflow process, wherein the intelligent power module are the heat dissipation structure are disposed on the lead frame by a same fixture.

7. The intelligent power module according to claim 1, wherein at least one chip is disposed on the lead frame, and at least another chip is disposed on the heat dissipation structure.

8. The intelligent power module according to claim 1, wherein the portions of the lead frame inside the encapsulating material structure do not include a downset.

9. The intelligent power module according to claim 1, wherein a bent structure is formed on a portion of the lead frame outside the encapsulating material structure.

10. An intelligent power module manufacturing method, including:
providing a fixture;
disposing a heat dissipation structure on the fixture;
placing a lead frame on the fixture, and fastening the lead frame on the heat dissipation structure, wherein all portions of the lead frame are at a same planar level;
placing at least one chip on the lead frame, and fastening the chip on the lead frame;
taking out the lead frame with the fastened heat dissipation structure and the fastened chip from the fixture; and
providing a packaging material, to form an encapsulating material structure encapsulating the lead frame fastened with the heat dissipation structure and the chip.

11. The intelligent power module manufacturing method according to claim 10, wherein after forming the encapsulating material structure, a bent structure of a portion of the lead frame outside the encapsulating material structure is formed.

12. The intelligent power module manufacturing method according to claim 10, wherein the step of fastening the lead frame on the heat dissipation structure includes:
forming a plurality of bonding pads on the heat dissipation structure;
placing the lead frame on the bonding pads; and
performing reflow to fasten the heat dissipation structure on the lead frame.

13. The intelligent power module manufacturing method according to claim 10, wherein the step of fastening the at least one chip on the lead frame includes:
forming a die attach adhesive on the lead frame;
placing the chip on the die attach adhesive; and
baking the die attach adhesive to fasten the chip on the lead frame.

14. The intelligent power module manufacturing method according to claim 10, further including: forming a bonding wire connected between the chip and the lead frame, or between the chips when the at least one chip includes a plurality of chips.

15. The intelligent power module manufacturing method according to claim 10, further including: placing at least another chip on the heat dissipation structure, and fastening the at least another chip on the heat dissipation structure.
